(19) United States
(12) Patent Application Publication
(10) Pub. No.: US 2026/0026353 A1
(43) Pub. Date: Jan. 22, 2026

(54) SEMICONDUCTOR DEVICE

(71) Applicant: Renesas Electronics Corporation, Tokyo (JP)

(72) Inventors: Hiroaki SEKIKAWA, Tokyo (JP); Fumitoshi TAKAHASHI, Tokyo (JP)

(21) Appl. No.: 19/211,556

(22) Filed: May 19, 2025

(30) Foreign Application Priority Data
Jul. 19, 2024 (JP) 2024-116129

(51) Int. Cl. H01L 23/58; H01L 23/522; H10D 1/47

(52) U.S. Cl. CPC H01L 23/585; H01L 23/5223; H10D 1/47

(57) ABSTRACT

A semiconductor device capable of suppressing an increase in chip area due to the widening of a conductor located on the topmost layer of a sealing ring is provided. The semiconductor device includes a semiconductor substrate and the sealing ring. The sealing ring is formed on a periphery of the semiconductor substrate in a plan view. The sealing ring includes a plurality of conductors stacked on each other. Each of the plurality of conductors has an inner peripheral edge and an outer peripheral edge. An inner peripheral edge of a first conductor, which is located on the topmost layer of the plurality of conductors, is positioned more inward than any of inner peripheral edges of a plurality of second conductors located below the first conductor in a plan view.

### CROSS-REFERENCE TO RELATED APPLICATIONS

The disclosure of Japanese Patent Application No. 2024-116129 filed on Jul. 19, 2024, including the specification, drawings and abstract is incorporated herein by reference in its entirety.

### BACKGROUND

The present disclosure relates to a semiconductor device.

A semiconductor device described in Japanese Unexamined Patent Application Publication No. 2019-114673 (Patent Document 1) includes a semiconductor substrate, a sealing ring formed on a periphery of the semiconductor substrate, a passivation film and a polyimide film. The sealing ring comprises a plurality of conductors and a plurality of plugs. The plurality of conductors is stacked. Each of the plurality of plugs connects two adjacent conductors. However, one of the plurality of plugs connects the conductor located at the lowermost layer to the semiconductor substrate. The passivation film covers the conductor located at the uppermost t layer. The polyimide film is formed on the passivation film.

### SUMMARY

When a thickness of a conductor located at an uppermost layer increases, the adhesion of a polyimide film decreases. Therefore, when increasing the thickness of the conductor located at the uppermost layer, it is necessary to increase a width of the conductor located at the uppermost layer to ensure the adhesion of the polyimide film. Other problems and novel features will become apparent from the description of this specification and the accompanying drawings.

A semiconductor device of the present disclosure includes a semiconductor substrate and a sealing ring. The sealing ring is formed on the periphery of the semiconductor substrate in plan view. The sealing ring includes a plurality of conductors stacked to each other. Each of the plurality of conductors has an inner peripheral edge and an outer peripheral edge. An inner peripheral edge of a first conductor located at the uppermost layer is positioned more inward than any of inner peripheral edges of the plurality of second conductors located below the first conductor in plan view.

According to the semiconductor device of the present disclosure, it is possible to suppress an increase in chip area as the width of the first conductor increases.

### BRIEF DESCRIPTION OF THE DRAWINGS

FIG. 1 is a plan view of a semiconductor device DEV1.

FIG. 2 is a cross-sectional view of the semiconductor device DEV1 at II-II in FIG. 1.

FIG. 3 is a manufacturing process diagram of the semiconductor device DEV1.

FIG. 4 is a cross-sectional view for explaining an ion-implantation step S2.

FIG. 5 is a cross-sectional view for explaining an element isolation film forming step S3.

FIG. 6 is a cross-sectional view for explaining a gate dielectric film forming step S4.

FIG. 7 is a cross-sectional view for explaining a gate electrode forming step S5.

FIG. 8 is a cross-sectional view for explaining an ion-implantation step S6.

FIG. 9 is a cross-sectional view for explaining a sidewall spacers forming step S7.

FIG. 10 is a cross-sectional view for explaining an ion-implantation step S8.

FIG. 11 is a cross-sectional view for explaining an interlayer insulating film forming step S9.

FIG. 12 is a cross-sectional view for explaining a plug forming step S10.

FIG. 13 is a cross-sectional view for explaining a wiring forming step S11.

FIG. 14 is a cross-sectional view for explaining a passivation film forming step S12.

FIG. 15 is a cross-sectional view for explaining a polyimide film forming step S13.

FIG. 16 is a cross-sectional view for explaining a wiring forming step S14.

FIG. 17 is a cross-sectional view of the semiconductor device DEV1 according to a first modified example.

FIG. 18 is a cross-sectional view of the semiconductor device DEV1 according to a second modified example.

FIG. 19 is a plan view of the semiconductor device DEV1 according to a third modified example.

FIG. 20 is a cross-sectional view of the semiconductor device DEV1 according to the third modified example at XX-XX in FIG. 19.

FIG. 21 is a cross-sectional view of the semiconductor device DEV1 according to the third modified example at XXI-XXI in FIG. 20.

FIG. 22 is a cross-sectional view of a semiconductor device DEV2.

FIG. 23 is a cross-sectional view of the semiconductor device DEV2 at XXIII-XXIII in FIG. 22.

FIG. 24 is a cross-sectional view of the semiconductor device DEV2 according to a modified example.

FIG. 25 is a cross-sectional view of the semiconductor device DEV2 according to the modified example at XXV-XXV in FIG. 24.

### DETAILED DESCRIPTION

The embodiments of the present disclosure will be described with reference to the drawings. In the following drawings, the same or corresponding parts are denoted by the same reference numerals, and redundant description will not be repeated.

### First Embodiment

A semiconductor device DEV1 according to the first embodiment will be described.

### (Configuration of Semiconductor Device DEV1)

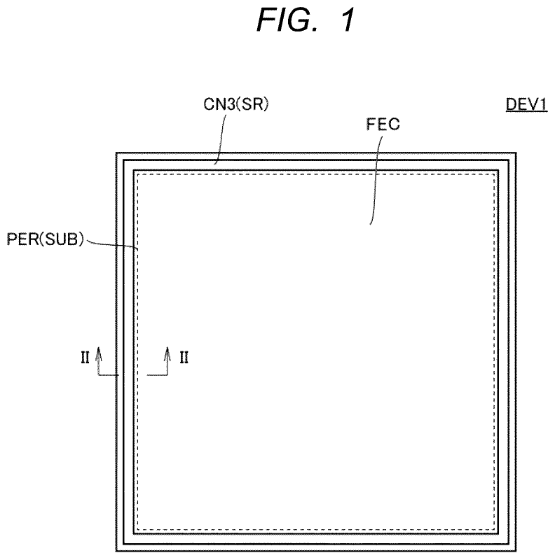

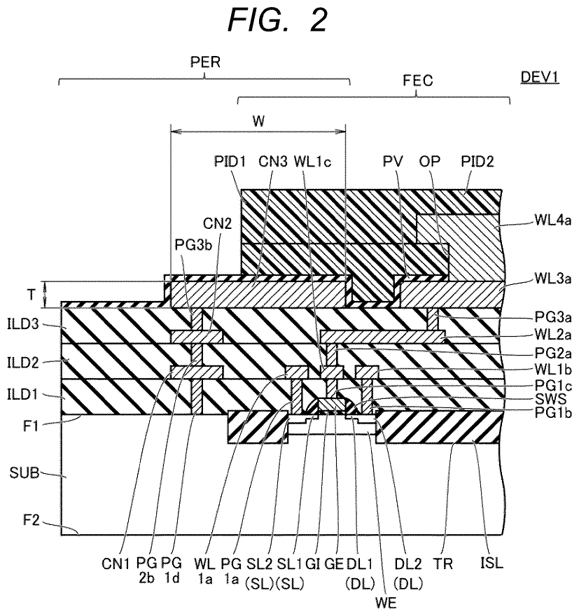

As shown in FIG. 1 and FIG. 2, the semiconductor device DEV1 includes a semiconductor substrate SUB. The semiconductor substrate SUB has a circuit element formation region CEF and a periphery PER of the semiconductor substrate SUB so as to surround the circuit element formation region CEF. The periphery PER partially overlaps with the circuit element formation region CEF in plan view. The semiconductor substrate SUB has an upper surface F1 and a bottom surface F2 located opposite the upper surface F1. The semiconductor substrate SUB is formed of, for example, monocrystalline silicon.

Within the semiconductor substrate SUB, a source layer SL, a drain layer DL and a well layer WE are formed. The source layer SL and the drain layer DL are positioned on the upper surface F1 with a space between them. The well layer WE is positioned on the upper surface F1 so as to surround the source layer SL and the drain layer DL. The conductivity type of the source layer SL and the drain layer DL is opposite to that of the well layer WE. For example, the conductivity type of the source layer SL and the drain layer DL is n-type, and the conductivity type of the well layer WE is p-type.

The source layer SL includes a first portion SL1 and a second portion SL2. The first portion SL1 is located between the second portion SL2 and the drain layer DL. The drain layer DL includes a first portion DL1 and a second portion DL2. The first portion DL1 is located between the second portion DL2 and the source layer SL. An impurity concentration in the first portion SL1 is lower than that in the second portion SL2, and an impurity concentration in the first portion DL1 is lower than that in the second portion DL2. That is, the source layer SL and the drain layer DL have a Lightly Doped Diffusion (LDD) structure.

The semiconductor device DEV1 further includes a gate dielectric film GI. The gate dielectric film GI is formed on the upper surface F1 between the source layer SL and the drain layer DL. The gate dielectric film GI is formed of, for example, silicon oxide. The semiconductor device DEV1 further includes a gate electrode GE. The gate electrode GE is formed on the gate dielectric film GI. The gate electrode GE is formed of, for example, polycrystalline silicon containing dopants. The source layer SL, the drain layer DL, the well layer WE, the gate dielectric film GI, and the gate electrode GE constitute a transistor.

The semiconductor device DEV1 further includes sidewall spacers SWS. The sidewall spacers SWS are formed on the first portion SL1 and the first portion DL1 so as to contact side surfaces of the gate dielectric film GI and the gate electrode GE. The sidewall spacers SWS is formed of, for example, silicon nitride.

A trench TR is formed on the upper surface F1. The trench TR extends from the upper surface F1 toward the bottom surface F2. The trench TR surrounds the above-mentioned transistor in plan view. The semiconductor device DEV1 further includes an element isolation film ISL. The element isolation film ISL is formed in the trench TR. This electrically isolates the above-mentioned transistor from other elements. The element isolation film ISL is formed of, for example, silicon oxide.

The semiconductor device DEV1 further includes an interlayer insulating film ILD1. The interlayer insulating film ILD1 is formed on the upper surface F1 so as to cover the gate electrode GE, the sidewall spacers SWS and the element isolation film ISL. The interlayer insulating film ILD1 is formed of, for example, silicon oxide. The semiconductor device DEV1 further includes an interlayer insulating film ILD2 and an interlayer insulating film ILD3. The interlayer insulating film ILD2 is formed on the interlayer insulating film ILD1, and the interlayer insulating film ILD3 is formed on the interlayer insulating film ILD2. The interlayer insulating films ILD2 and ILD3 are formed of, for example, silicon oxide.

The semiconductor device DEV1 further includes a wiring WL1a, a wiring WL1b and a wiring WL1c. The wirings WL1a, WL1b and WL1c are formed on the interlayer insulating film ILD1 and are covered by the interlayer insulating film ILD2. The wirings WL1a, WL1b and WL1c are formed of, for example, aluminum or an aluminum alloy. The semiconductor device DEV1 further includes a plug PG1a, a plug PG1b and a plug PG1c. The plugs PG1a, PG1b and PG1c are formed in the interlayer insulating film ILD1. The plug PG1a electrically connects the wiring WL1a and the source layer SL. The plug PG1b electrically connects the wiring WL1b and the drain layer DL. The plug PG1c electrically connects the wiring WL1c and the gate electrode GE. The plugs PG1a, PG1b and PG1c are formed of, for example, tungsten.

The semiconductor device DEV1 further includes a wiring WL2a. The wiring WL2a is formed on the interlayer insulating film ILD2 and is covered by the interlayer insulating film ILD3. The wiring WL2a is formed of, for example, aluminum or an aluminum alloy. The semiconductor device DEV1 further includes a plug PG2a. The plug PG2a is formed in the interlayer insulating film ILD2. The plug PG2a electrically connects the wiring WL2a and the wiring WL1c. The plug PG2a is formed of, for example, tungsten.

The semiconductor device DEV1 further includes a wiring WL3a. The wiring WL3a is formed on the interlayer insulating film ILD3. The wiring WL3a is formed of, for example, aluminum or an aluminum alloy. The semiconductor device DEV1 further includes a plug PG3a. The plug PG3a is formed in the interlayer insulating film ILD3. The plug PG3a electrically connects the wiring WL3a and the wiring WL2a. The plug PG3a is formed of, for example, tungsten.

The semiconductor device DEV1 further includes a sealing ring SR. The sealing ring SR is formed on the periphery PER. The sealing ring SR is formed over an entire circumference of the periphery PER in plan view. The sealing ring SR includes a conductor CN1, a conductor CN2, a conductor CN3, a plug PG1d, a plug PG2b and a plug PG3b.

The conductor CN1 is formed on the interlayer insulating film ILD1 and is covered by the interlayer insulating film ILD2. The conductor CN2 is formed on the interlayer insulating film ILD2 and is covered by the interlayer insulating film ILD3. The conductor CN3 is formed on the interlayer insulating film ILD3. From another perspective, the conductor CN1 is formed in the same layer as the wirings WL1a, WL1b and WL1c, the conductor CN2 is formed in the same layer as the wiring WL2a, and the conductor CN3 is formed in the same layer as the wiring WL3a. The conductors CN1, CN2 and CN3 are formed of, for example, aluminum or an aluminum alloy.

The plug PG1d is formed in the interlayer insulating film ILD1 and connects the conductor CN1 and the upper surface F1. The plug PG2b is formed in the interlayer insulating film ILD2 and connects the conductor CN2 and the conductor CN1. The plug PG3b is formed in the interlayer insulating film ILD3 and connects the conductor CN3 and the conductor CN2. The plugs PG1d, PG2b and PG3b are formed of, for example, tungsten.

An inner peripheral edge of the conductor CN3 is located inside inner peripheral edges of the conductor CN2 and the conductor CN1 in plan view. An outer peripheral edge of the conductor CN3 overlaps with outer peripheral edges of the conductor CN2 and the conductor CN1 in plan view. The source layer SL, the gate dielectric film GI, and the gate electrode GE overlap with the conductor CN3 in plan view. That is, at least a part of the above-mentioned transistor overlaps with the conductor CN3 in plan view.

A thickness of the conductor CN3 is denoted as thickness T. A width of the conductor CN3, i.e., a distance between the inner peripheral edge and the outer peripheral edge of the conductor CN3, is denoted as width W. The thickness T is, for example, 3 micrometers or more. The thickness T is, for example, 5 micrometers or less. The width W is, for example, 10 micrometers or more. The width W is, for example, 20 micrometers or less.

The semiconductor device DEV1 further includes a passivation film PV. The passivation film PV is formed on the interlayer insulating film ILD3 so as to cover the wiring WL3a and the conductor CN3. The passivation film PV is formed of, for example, silicon nitride.

The semiconductor device DEV1 further includes a polyimide film PID1. The polyimide film PID1 is formed on the passivation film PV. The edge (outer peripheral edge) of the polyimide film PID1 overlaps with the conductor CN3 in plan view. The edge of the polyimide film PID1 is located inside the outer peripheral edge of the conductor CN3 in plan view. The semiconductor device DEV1 includes a wiring WL4a. The wiring WL4a is formed on the polyimide film PID1. An opening OP is formed in the polyimide film PID1 and the passivation film PV. The wiring WL3a is exposed from the opening OP. The wiring WL4a is also formed in the opening OP. Thus, the wiring WL4a is electrically connected to the wiring WL3a. The wiring WL4a is formed of, for example, copper or a copper alloy. The semiconductor device DEV1 further includes a polyimide film PID2. The polyimide film PID2 is formed on the polyimide film PID1 so as to cover the wiring WL4a.

### (Manufacturing Method of Semiconductor Device DEV1)

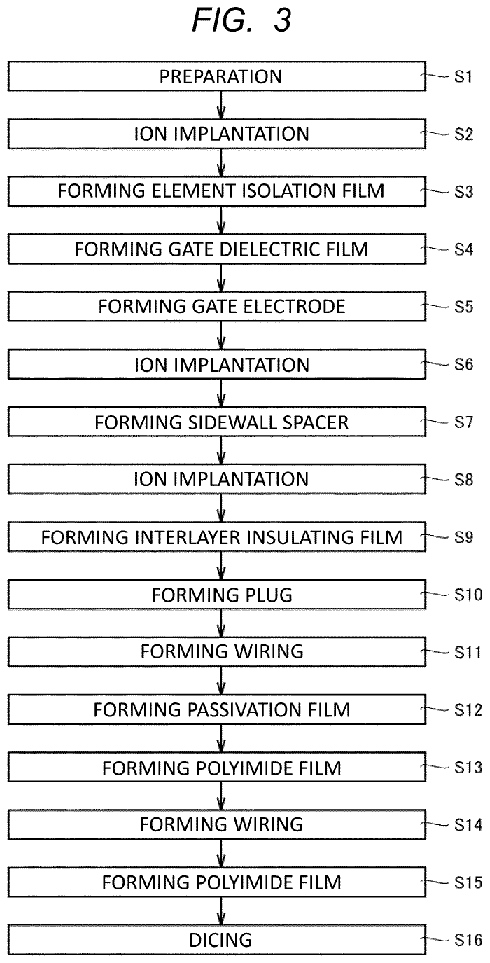

As shown in FIG. 3, a manufacturing method of the semiconductor device DEV1 includes a preparation step S1, an ion implantation step S2, an element isolation film forming step S3, a gate dielectric film forming step S4, a gate electrode forming step S5, an ion implantation step S6, a sidewall spacers forming step S7, and an ion implantation step S8. The manufacturing method of the semiconductor device DEV1 further includes an interlayer insulating film forming step S9, a plug forming step S10, a wiring forming step S11, a passivation film forming step S12, a polyimide film forming step S13, a wiring forming step S14, a polyimide film forming step S15 and a dicing step S16.

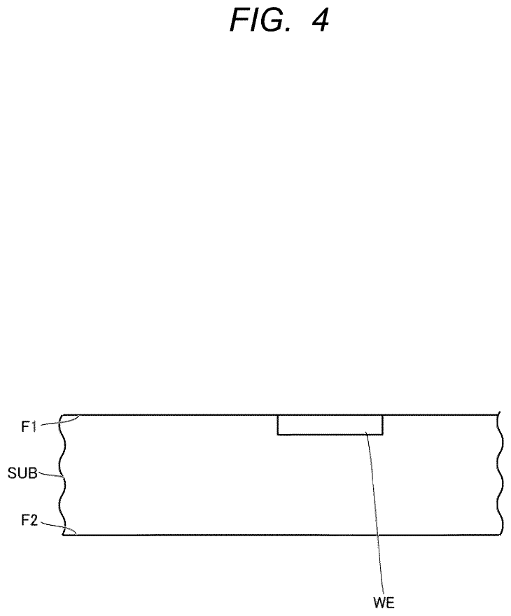

In the preparation step S1, the semiconductor substrate SUB is prepared. As shown in FIG. 4, in the ion implantation step S2, ion implantation is performed to form the well layer WE in the semiconductor substrate SUB.

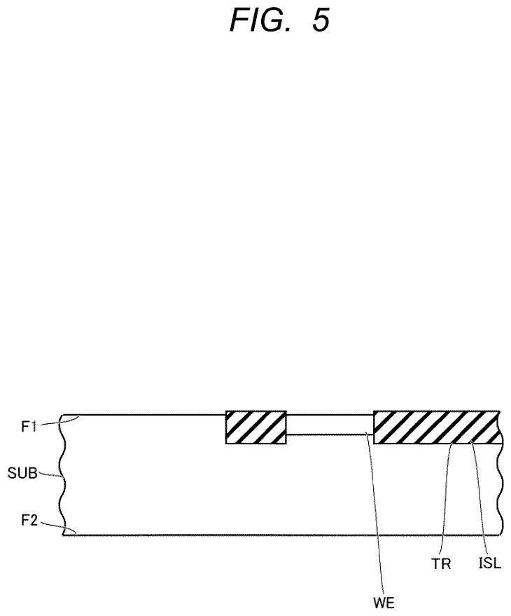

As shown in FIG. 5, in the element isolation film forming step S3, the trench TR and the element isolation film ISL are formed. In the element isolation film forming step S3, first, a hard mask is formed on the upper surface F1. Second, etching is performed on the upper surface F1 using the hard mask to form the trench TR. Third, for example, by a CVD (Chemical Vapor Deposition) method, the constituent material of the element isolation film ISL is embedded in the trench TR and formed on the upper surface F1. Fourth, the constituent material of the element isolation film ISL formed outside the trench TR is removed by, for example, a CMP method or etch-back. Thus, the element isolation film ISL is formed in the trench TR.

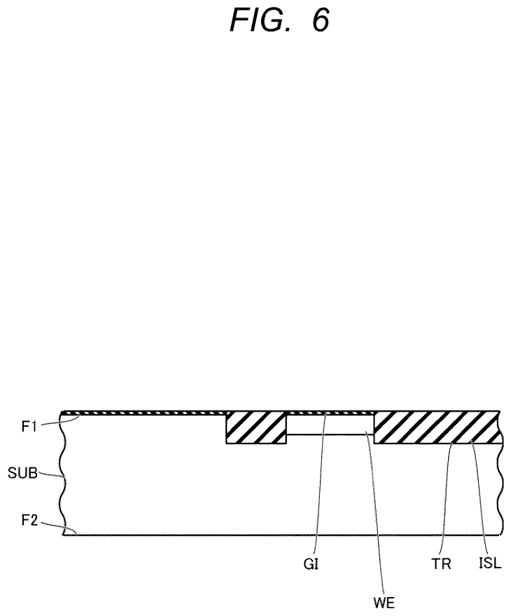

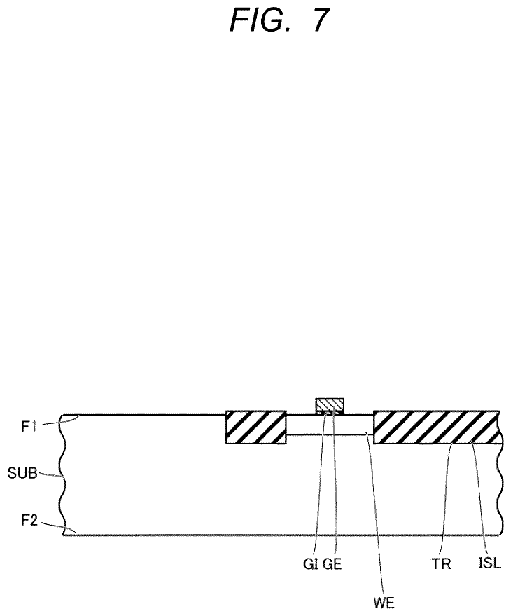

As shown in FIG. 6, in the gate dielectric film forming step S4, for example, thermal oxidation is performed to form the gate dielectric film GI on the upper surface F1. As shown in FIG. 7, in the gate electrode forming step S5, the gate electrode GE is formed on the gate dielectric film GI. In the gate electrode forming step S5, first, the constituent material of the gate electrode GE is formed on the gate dielectric film GI by, for example, a CVD method. Second, a resist pattern is formed on the constituent material of the gate electrode GE. Third, using the resist pattern, the constituent material of the gate electrode GE is patterned to form the gate electrode GE.

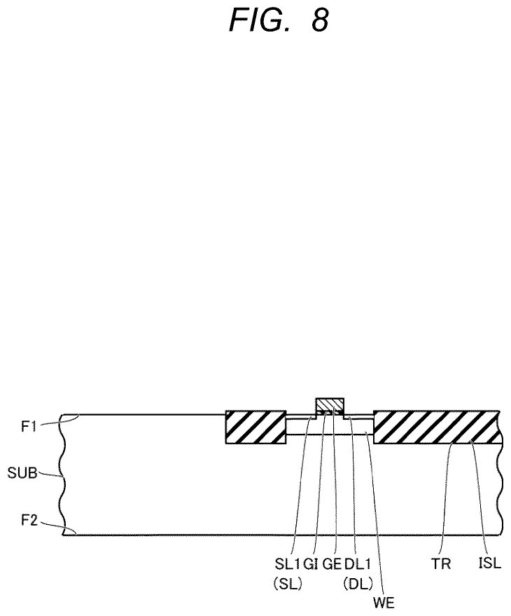

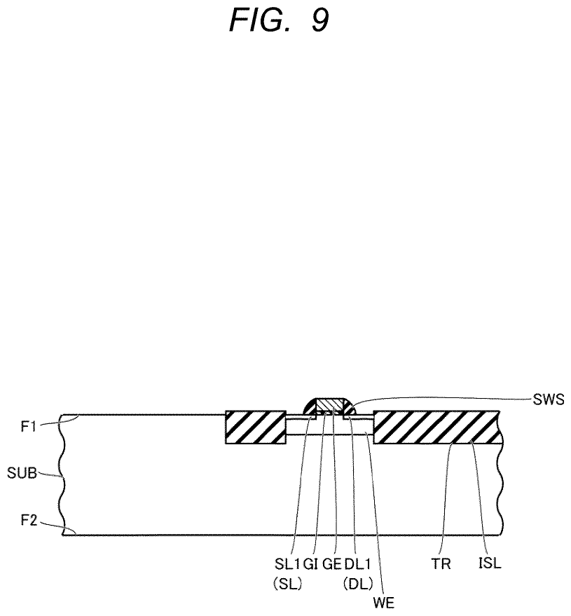

As shown in FIG. 8, in the ion implantation step S6, ion implantation is performed to form the first portion SL1 and the first portion DL1 in the semiconductor substrate SUB. As shown in FIG. 9, in the sidewall spacers forming step S7, the sidewall spacers SWS are formed on the upper surface F1 so as to contact the side surfaces of the gate dielectric film GI and the gate electrode GE. In the sidewall spacers forming step S7, first, for example, by a CVD method, the constituent material of the sidewall spacers SWS is formed on the upper surface F1 so as to cover the gate dielectric film GI, the gate electrode GE and the element isolation film ISL. Second, etch-back is performed on the constituent material of the sidewall spacers SWS. Thus, the sidewall spacers SWS are formed.

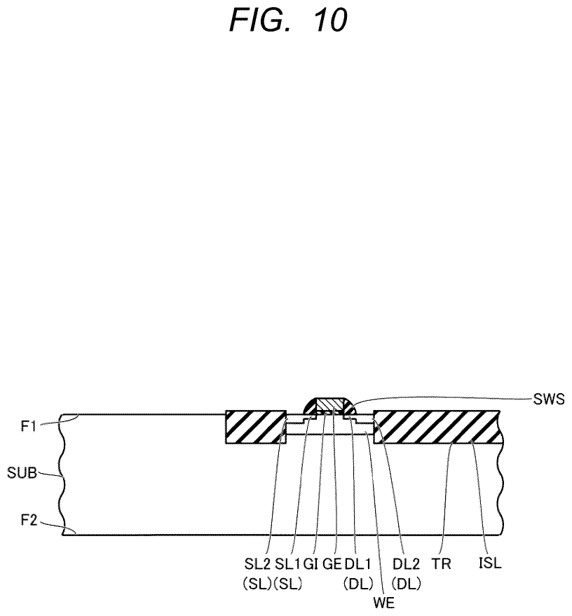

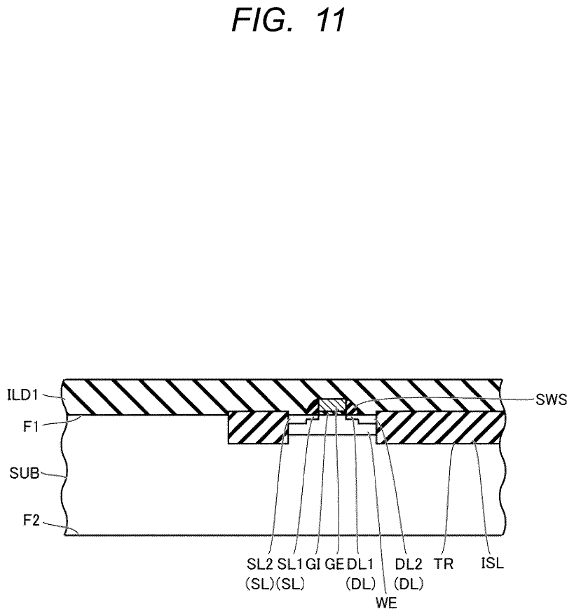

As shown in FIG. 10, in the ion implantation step S8, ion implantation is performed to form the second portion SL2 and the second portion DL2 in the semiconductor substrate SUB. As shown in FIG. 11, in the interlayer insulating film forming step S9, the interlayer insulating film ILD1 is formed on the upper surface F1 so as to cover the sidewall spacers SWS, the element isolation film ISL and the gate electrode GE. In the interlayer insulating film forming step S9, first, for example, by a CVD method, the interlayer insulating film ILD1 is formed on the upper surface F1 so as to cover the sidewall spacers SWS, the element isolation film ISL and the gate electrode GE. Second, an upper surface of the interlayer insulating film ILD1 is planarized by, for example, a CMP method.

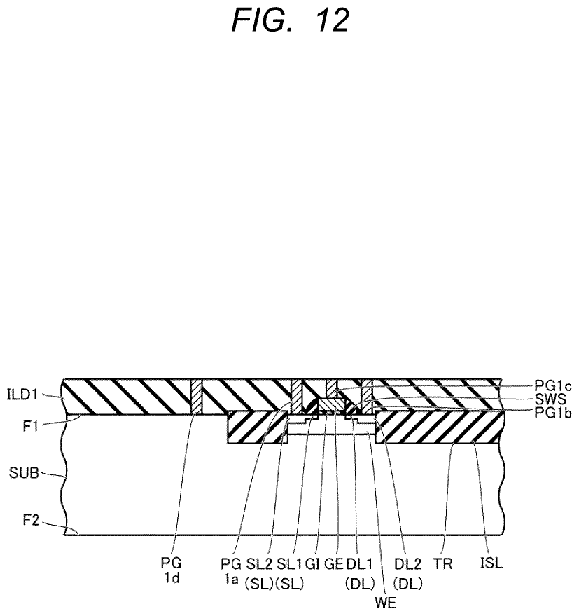

As shown in FIG. 12, in the plug forming step S10, the plugs PG1a, PG1b, PG1c and PG1d are formed in the interlayer insulating film ILD1. In the plug forming step S10, first, a resist pattern is formed on the interlayer insulating film ILD1. Second, using the resist pattern, etching is performed on the interlayer insulating film ILD1 to form a plurality of through holes in the interlayer insulating film ILD1. Third, for example, by a CVD method, the constituent material of the plugs PG1a, etc., is embedded in each of the plurality of through holes formed in the interlayer insulating film ILD and formed on the interlayer insulating film ILD1. Fourth, the constituent material of the plugs PG1a, etc., formed outside the plurality of through holes in the interlayer insulating film ILD is removed by, for example, a CMP method. Thus, the plugs PG1a, PG1b, PG1c and PG1d are formed in the interlayer insulating film ILD1.

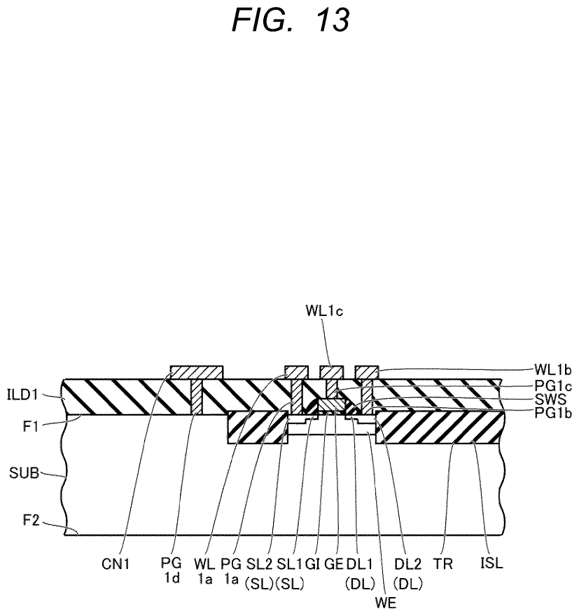

As shown in FIG. 13, in the wiring forming step S11, the wirings WL1a, WL1b, WL1c and the conductor CN1 are formed on the interlayer insulating film ILD1. In the wiring forming step S11, first, for example, by sputtering, the constituent material of the wirings WL1a, etc., is formed on the interlayer insulating film ILD1. Second, a resist pattern is formed on the constituent material of the wirings WL1a, etc. Third, using the resist pattern, etching is performed on the constituent material of the wirings WL1a, etc., to pattern the constituent material of the wirings WL1a, etc., and form the wirings WL1a, WL1b, WL1c and the conductor CN1. Thereafter, by sequentially repeating steps similar to the interlayer insulating film forming step S9, the plug forming step S10, and the wiring forming step S11, the interlayer insulating film ILD2, the plugs PG2a and PG2b, the wiring WL2a, the conductor CN2, the interlayer insulating film ILD3, the plugs PG3a and PG3b, the wiring WL3a and the conductor CN3 are formed.

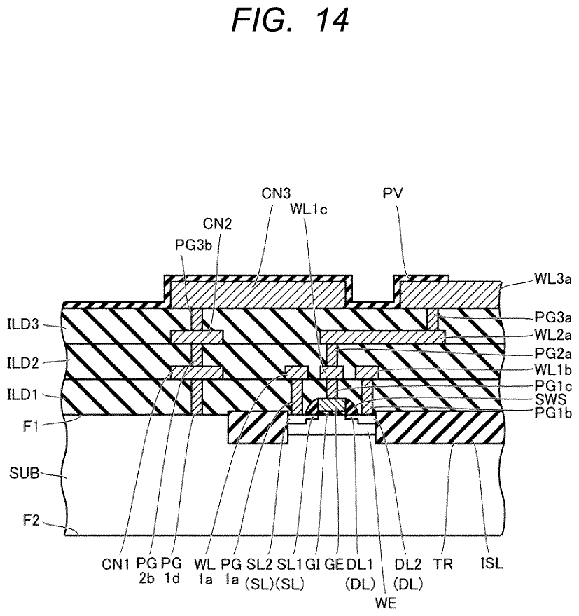

As shown in FIG. 14, in the passivation film forming step S12, the passivation film PV is formed on the interlayer insulating film ILD3 so as to cover the wiring WL3a and the conductor CN3. In the passivation film forming step S12, first, for example, by a CVD method, the constituent material of the passivation film PV is formed on the interlayer insulating film ILD3 so as to cover the wiring WL3a and the conductor CN3. Second, a resist pattern is formed on the passivation film PV. Third, using the resist pattern, etching is performed on the constituent material of the passivation film PV to pattern the constituent material of the passivation film PV and form the passivation film PV.

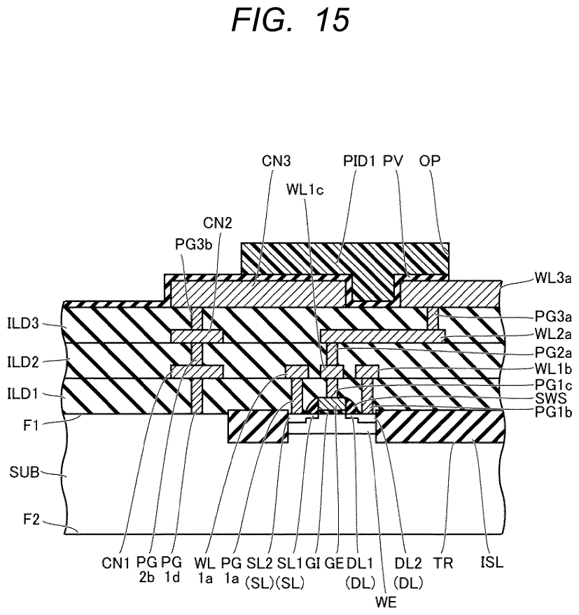

As shown in FIG. 15, in the polyimide film forming step S13, the polyimide film PID1 is formed on the passivation film PV. In the polyimide film forming step S13, the constituent material of the polyimide film PID1 is applied on the passivation film PV. Second, exposure and development are performed on the constituent material of the polyimide film PID1 to pattern the constituent material of the polyimide film PID1 and form the polyimide film PID1.

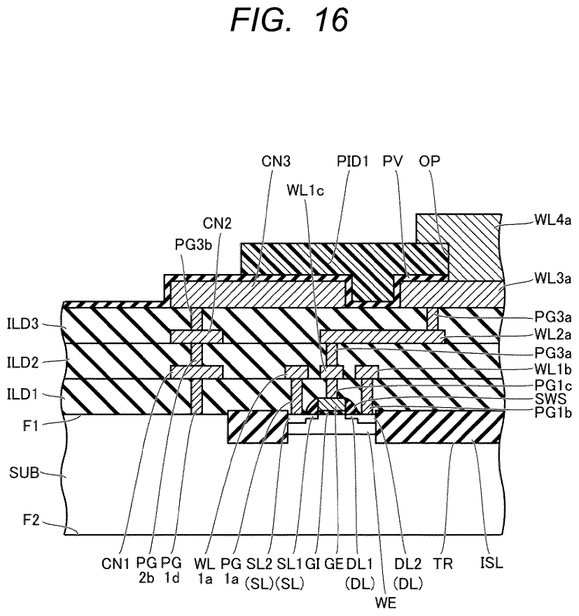

As shown in FIG. 16, in the wiring forming step S14, the wiring WL4a is formed on the polyimide film PID1 so as to be electrically connected to the wiring WL3a. In the wiring forming step S14, first, for example, by sputtering, a seed layer is formed on the polyimide film PID1, on the inner wall surface of the opening OP and on the wiring WL3a exposed from the opening OP. Second, a resist pattern is formed on the seed layer. Third, by performing electroplating, the constituent material of the wiring WL4a grows from the seed layer exposed from an opening of the resist pattern. Fourth, the seed layer under the resist pattern is removed by etching. Thus, the wiring WL4a is formed.

In the polyimide film forming step S15, by performing steps similar to the polyimide film forming step S13, the polyimide film PID2 is formed so as to cover the wiring WL4a. In the dicing step S16, the semiconductor substrate SUB, the interlayer insulating film ILD1, the interlayer insulating film ILD2 and the interlayer insulating film ILD3 are cut along the scribe lines. In this way, the structure of the semiconductor device DEV1 shown in FIGS. 1 and 2 is formed.

### First Modified Example

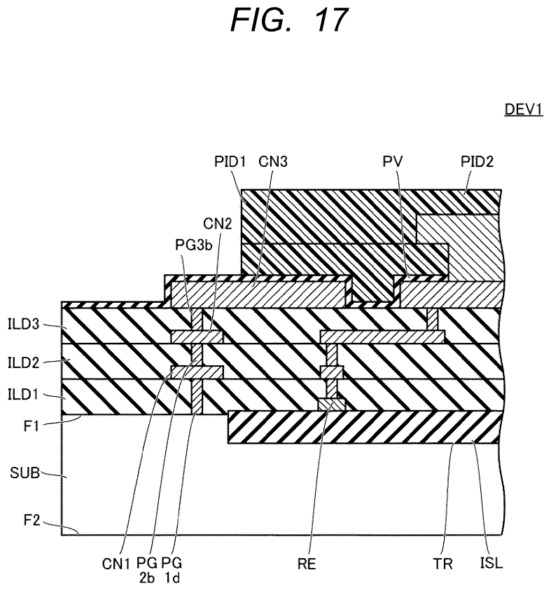

As shown in FIG. 17, in the semiconductor device DEV1, a resistive element RE may be formed on the element isolation film ISL overlapping with the conductor CN3 in a plan view. The resistive element RE is formed of, for example, polycrystalline silicon containing dopants. The resistive element RE is formed in the same step as the gate electrode GE. Thus, in the semiconductor device DEV1, a circuit element formed to overlap with the conductor CN3 in a plan view may be a passive element like the resistive element RE rather than an active element like a transistor.

### Second Modified Example

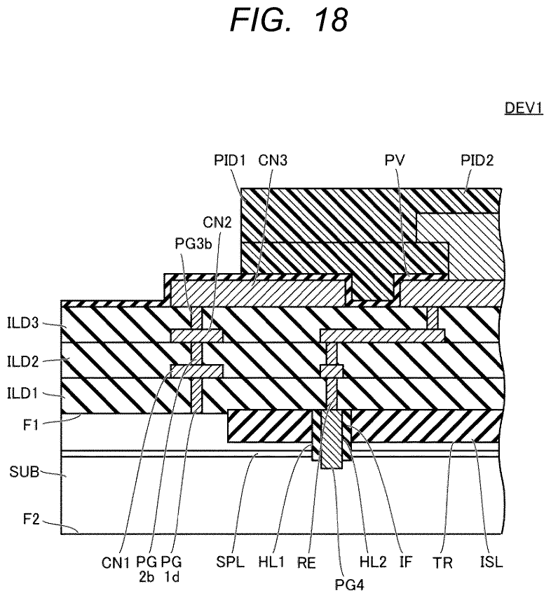

As shown in FIG. 18, in the semiconductor device DEV1, a separation layer SPL is formed in the semiconductor substrate SUB. The separation layer SPL is an impurity layer into which dopants are introduced, and a top portion of the semiconductor substrate SUB located between the separation layer SPL and the upper surface F1 is electrically isolated from a bottom portion of the semiconductor substrate SUB located between the separation layer SPL and the bottom surface F2 by the separation layer SPL.

In the semiconductor device DEV1, a hole HL1 is formed in the element isolation film ISL and the semiconductor substrate SUB. The hole HL1 penetrates the element isolation film ISL and reaches the portion of the semiconductor substrate SUB located between the separation layer SPL and the bottom surface F2. An insulating film IF is formed inside the hole HL1. In the semiconductor device DEV1, a hole HL2 is formed within the insulating film IF and the semiconductor substrate SUB. The hole HL2 penetrates the insulating film IF and reaches the portion of the semiconductor substrate SUB located between the separation layer SPL and the bottom surface F2. A plug PG4 is formed inside the hole HL2. The plug PG4 overlaps with the conductor CN3 in plan view. The plug PG4 is formed of, for example, polycrystalline silicon containing dopants. The plug PG4 is electrically connected to the portion of the semiconductor substrate SUB located between the separation layer SPL and the bottom surface F2, while it is electrically insulated from the portion of the semiconductor substrate SUB located between the separation layer SPL and the upper surface F1. This allows the potential of the portion of the semiconductor substrate SUB located between the separation layer SPL and the bottom surface F2 to be fixed. Thus, in the semiconductor device DEV1, a structure other than the circuit element may be formed at a position overlapping with the conductor CN3 in plan view. As a structure other than the circuit element, for example, a dummy pattern may be formed at a position overlapping with the conductor CN3 in plan view.

### Third Modified Example

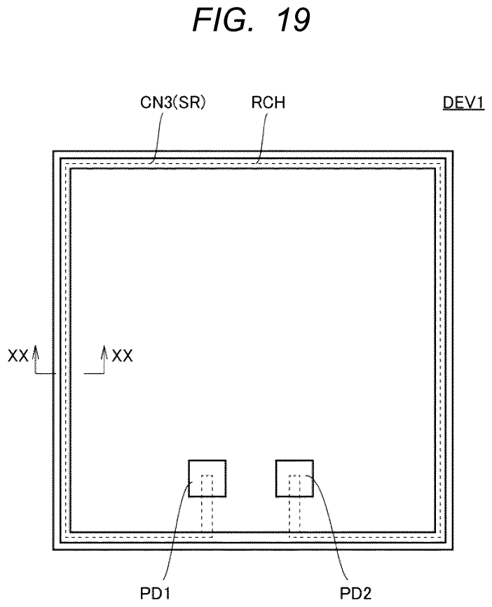

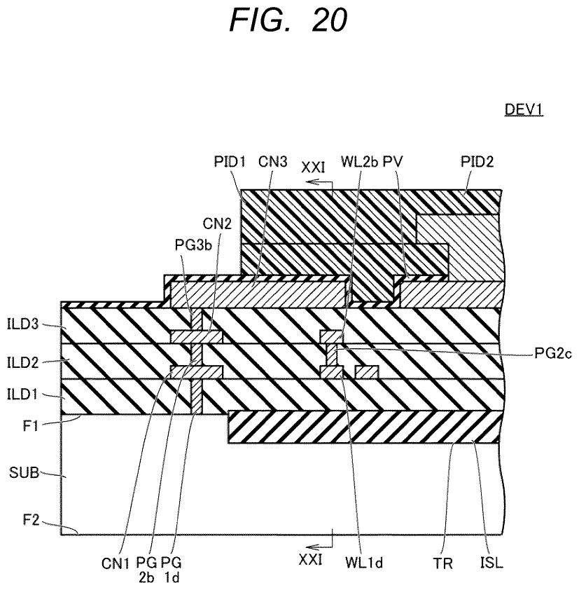

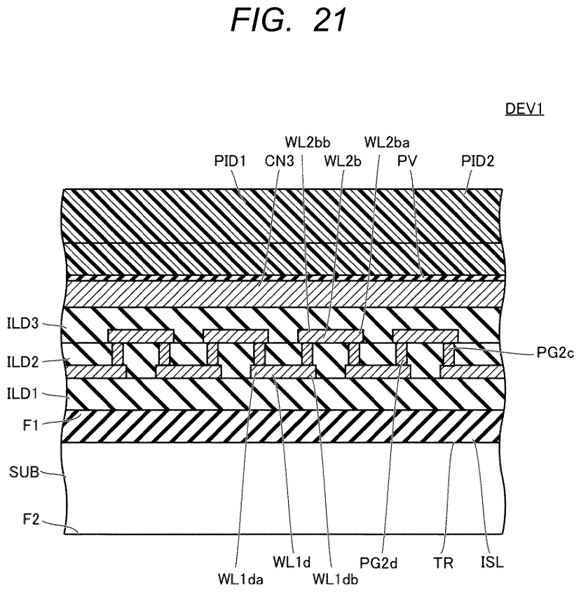

As shown in FIGS. 19, 20 and 21, in the semiconductor device DEV1, a chain resistor RCH may be formed to overlap with the conductor CN3 in plan view. The chain resistor RCH includes a plurality of wirings WL2b, a plurality of wirings WL1d, a plurality of plugs PG2c and a plurality of plugs PG2d. The chain resistor RCH is formed, for example, along the entire circumference of the periphery PER in plan view.

The plurality of wirings WL2b is formed in the same layer. More specifically, the plurality of wirings WL2b is formed in the same layer as the wiring WL2a. The plurality of wirings WL1d is formed in the same layer. More specifically, the plurality of wirings WL1d is formed in the same layer as the wirings WL1a, WL1b and WL1c. The plurality of wirings WL2b and the plurality of wirings WL1d are formed of, for example, aluminum or an aluminum alloy. From another perspective, the plurality of wirings WL1d is formed in the same process as the wirings WL1a, WL1b and WL1c, and the wirings WL2b are formed in the same process as the wiring WL2a.

The plurality of wirings WL2b is arranged spaced apart along the periphery PER in plan view, and the plurality of wirings WL1d is arranged spaced apart along the periphery PER in plan view. Each of the plurality of wirings WL2b has an end WL2ba and an end WL2bb. Each of the plurality of wirings WL1d has an end WL1da and an end WL1db. In plan view, one end WL2ba of the two adjacent wirings WL2b overlaps with the end WL1da of one wiring WL1d, and the other end WL2bb of the two adjacent wirings WL2b overlaps with the end WL1db of the same wiring WL1d.

The plurality of plugs PG2c and the plurality of plugs PG2d are formed within the interlayer insulating film ILD2. The plurality of plugs PG2c and the plurality of plugs PG2d are formed of, for example, tungsten. From another perspective, the plurality of plugs PG2c and the plurality of plugs PG2d are formed in the same process as the plug PG2a. Each of the plurality of plugs PG2c electrically connects the overlapping ends WL2ba and WL1da in plan view. Each of the plurality of plugs PG2d electrically connects the overlapping ends WL2bb and WL1db in plan view.

The semiconductor device DEV1 may include pads PD1 and PD2. The pads PD1 and PD2 are formed on the interlayer insulating film ILD3. The pads PD1 and PD2 are formed of aluminum or an aluminum alloy. From another perspective, the pads PD1 and PD2 are formed in the same process as the wiring WL3a and the conductor CN3. One end of the chain resistor RCH is electrically connected to the pad PD1, and the other end of the chain resistor RCH is electrically connected to the pad PD2.

During the dicing process S16, the propagation of cracks generated during dicing is usually stopped by the sealing ring SR. However, if the propagation of cracks is not stopped by the sealing ring SR, damage may occur to the chain resistor RCH due to the propagation of cracks, resulting in a change in the electrical resistance value of the chain resistor RCH. Therefore, by forming the chain resistor RCH and measuring the electrical resistance value between the pads PD1 and PD2 after manufacturing the semiconductor device DEV1, it can be confirmed whether cracks generated during dicing in the dicing process S16 have propagated to the inside of the semiconductor device DEV1.

### (Effects of Semiconductor Device DEV1)

To pass a large current through the semiconductor device DEV1, it is necessary to increase a thickness of the wiring WL3a. Consequently, the thickness (thickness T) of the conductor CN3 also increases. As the thickness T increases, it is necessary to increase the width W to ensure the adhesion of the polyimide film PID1.

In the semiconductor device DEV1, the inner peripheral edge of the conductor CN3 is located inside the inner peripheral edge of the conductor CN2 and the inner peripheral edge of the conductor CN1 in plan view, and the circuit element such as the active element or the passive element, a structure other than the circuit element such as a substrate contact or a dummy pattern, and a structure for inspecting the semiconductor device DEV1 are formed at a position overlapping with the conductor CN3 in plan view. In other words, in the semiconductor device DEV1, the space under the conductor CN3 is effectively utilized as a space for forming circuit elements and structures other than circuit elements, so that even if the width W increases, the increase in chip area is suppressed.

### Second Embodiment

A semiconductor device DEV2 according to the second embodiment will be described. Here, differences from the semiconductor device DEV1 will be mainly described, and redundant description will not be repeated.

### (Configuration of Semiconductor Device DEV2)

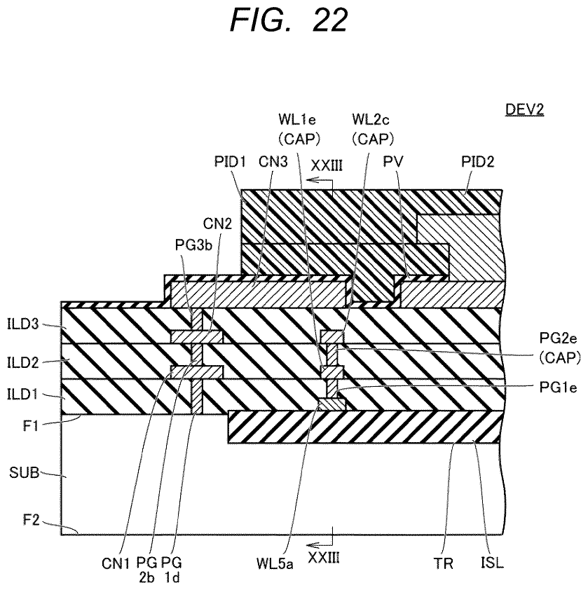

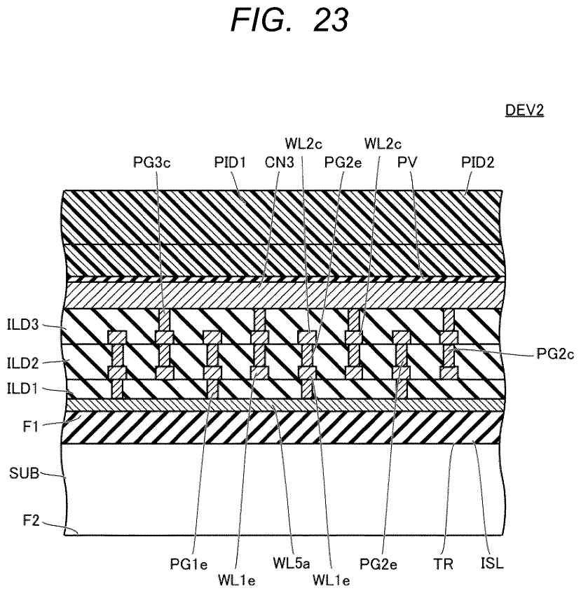

As shown in FIGS. 22 and 23, the semiconductor device DEV2 includes a capacitor CAP. The capacitor CAP includes a plurality of wirings WL2c, a plurality of wirings WL1e and a plurality of plugs PG2e.

The plurality of wirings WL2c is formed in the same layer. More specifically, the plurality of wirings WL2c is formed in the same layer as a wiring WL2a. The plurality of wirings WL1e is formed in the same layer. More specifically, the plurality of wirings WL1e is formed in the same layer as wirings WL1a, WL1b, and WL1c. The plurality of wirings WL2c and the plurality of wirings WL1e are formed of, for example, aluminum or an aluminum alloy. From another perspective, the plurality of wirings WL1e is formed in the same process as the wirings WL1a, WL1b and WL1c, and the wirings WL2c are formed in the same process as the wiring WL2a. The plurality of plugs PG2e is formed within an interlayer insulating film ILD2. The plug PG2e is formed of, for example, tungsten. From another perspective, the plug PG2e is formed in the same process as the plug PG2a.

The plurality of wirings WL2c is arranged spaced apart along the periphery PER in plan view to overlap with a conductor CN3. The plurality of wirings WL1e is arranged spaced apart along the periphery PER in plan view. Each of the plurality of wirings WL1e faces each of the plurality of wirings WL2c with the interlayer insulating film ILD2 interposed therebetween. Each of the plurality of plugs PG2e electrically connects the facing the wirings WL2c and WL1e.

The semiconductor device DEV2 further includes a wiring WL5a. The wiring WL5a is formed on an element isolation film ISL to overlap with the plurality of wirings WL2c and the plurality of wirings WL1e in plan view. The wiring WL5a is formed of, for example, polycrystalline silicon containing dopants. From another perspective, the wiring WL5a is formed in the same process as a gate electrode GE.

The semiconductor device DEV2 further includes a plurality of plugs PG3c and a plurality of plugs PG1e. The plurality of plugs PG3c are formed within an interlayer insulating film ILD3. The plurality of plugs PG3c are formed of, for example, tungsten. From another perspective, the plurality of plugs PG3c are formed in the same process as the plug PG3a. The plurality of plugs PG1e are formed within an interlayer insulating film ILD1. The plurality of plugs PG1e are formed of, for example, tungsten. From another perspective, the plurality of plugs PG1e are formed in the same process as the plugs PG1a, PG1b and PG1c.

Each of the plurality of plugs PG3c electrically connects each of the plurality of wirings WL2c and the conductor CN3. However, the wirings WL2c electrically connected to the conductor CN3 by the plugs PG3c are alternately arranged with the wirings WL2c not electrically connected to the conductor CN3 by the plugs PG3c. Each of the plurality of plugs PG1e electrically connects each of the plurality of wirings WL1e and the wiring WL5a. However, the plug PG1e is not connected to the wirings WL1e electrically connected to the conductor CN3 by the plug PG3c, the wiring WL2c and the plug PG2c. In other words, the wiring WL1e electrically connected to the wiring WL5a via the plug PG1e is alternately arranged with the wiring WL1e that is not electrically connected to the wiring WL5a via the plug PG1e.

For example, a VDD potential is applied to the wiring WL5a. A ground potential is applied to the conductor CN3, for example. Therefore, a charge accumulates between a connected structure to the wiring WL5a which consists of the wiring WL2c, the plug PG2e and the wiring WL1e, and a connected structure to the conductor CN3 which consists of the wiring WL2c, the plug PG2c and the wiring WL1e.

### Modified Example

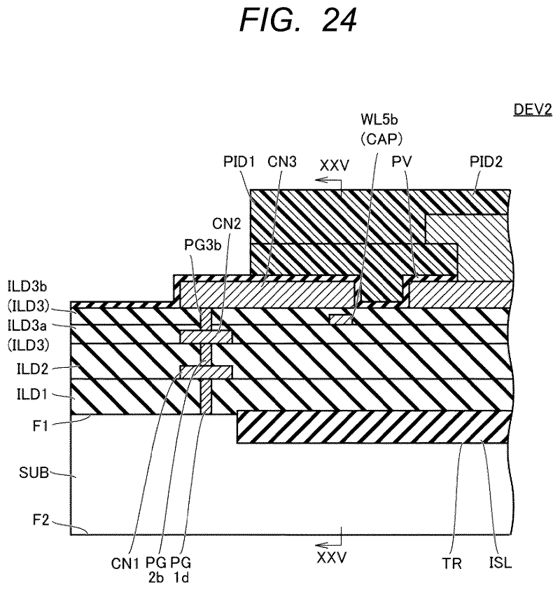

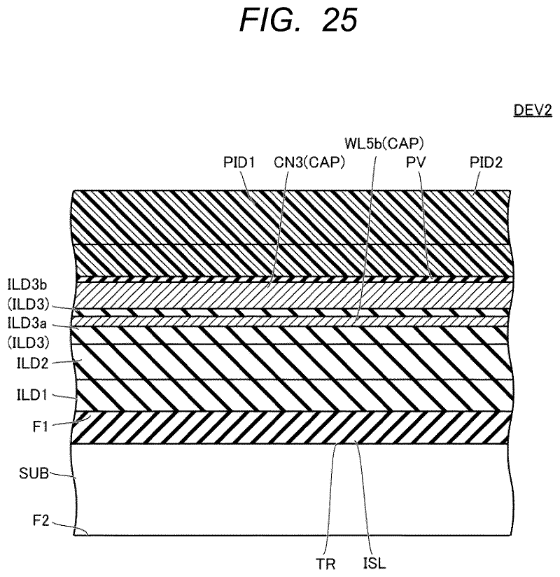

As shown in FIGS. 24 and 25, in the semiconductor device DEV2, the interlayer insulating film ILD3 may have a first layer ILD3a and a second layer ILD3b. The first layer ILD3a is formed on the interlayer insulating film ILD2, and the second layer ILD3b is formed on the first layer ILD3a. Additionally, the semiconductor device DEV2 may have a wiring WL5b. The wiring WL5b is arranged on the first layer ILD3a and is covered by the second layer ILD3b. The wiring WL5b extends along the periphery PER so as to overlap with the conductor CN3 in plan view. For example, a VDD potential is applied to the wiring WL5b. A ground potential is applied to the conductor CN3, for example. Therefore, charge is accumulated between the conductor CN3 and the wiring WL5b, and the conductor CN3 and the wiring WL5b function as the capacitor CAP.

### (Effects of Semiconductor Device DEV2)

In the semiconductor device DEV2, the capacitor CAP is formed at a position overlapping with the conductor CN3 in plan view. In other words, in the semiconductor device DEV2, the space under the conductor CN3 is effectively utilized as a space for forming the capacitor CAP, so even if a width W increases, the increase in chip area is suppressed.

Although the invention made by the present inventors has been described in detail based on the embodiments, it is needless to say that the present invention is not limited to the above-embodiments and can be variously modified without 5 described departing from the gist thereof.

What is claimed is:

1. A semiconductor device comprising:
a circuit element formation region formed on a semiconductor substrate; and
a sealing ring formed along a periphery of the semiconductor substrate so as to surround the circuit element formation region, wherein
the sealing ring includes a plurality of conductors stacked on each other,
the plurality of conductors includes a first conductor located at an uppermost layer of the plurality of conductors and a plurality of second conductors other than the uppermost layer of the plurality of conductors
an inner peripheral edge of the first conductor is located inside an inner peripheral edge of the plurality of second conductors, in plan view.

2. The semiconductor device according to claim 1, wherein
an outer peripheral edge of the first conductor overlaps with an outer peripheral edge of the plurality of second conductors, in plan view.

3. The semiconductor device according to claim 1, further comprising:
a first wiring formed in the same layer of the first conductor in the circuit element formation region;
a passivation film covering the first conductor and the first wiring;
a polyimide film formed on the passivation film; and
a second wiring formed on the polyimide film and electrically connected to the first wiring.

4. The semiconductor device according to claim 3, wherein
an end of the polyimide film overlaps with the first conductor in plan view.

5. The semiconductor device according to claim 4, wherein
a thickness of the first conductor is 3 micrometers or more.

6. The semiconductor device according to claim 4, wherein
a distance between an inner peripheral edge and an outer peripheral edge of the first conductor is 10 micrometers or more.

7. The semiconductor device according to claim 1, further comprising:
a circuit element formed in the circuit element formation region, wherein
the circuit element partially overlaps with the first conductor in plan view.

8. The semiconductor device according to claim 7, wherein
the circuit element is an active element.

9. The semiconductor device according to claim 7, wherein
the circuit element is a passive element.

10. The semiconductor device according to claim 1, further comprising:
an impurity layer formed in the semiconductor substrate, and
a first plug formed in the semiconductor substrate, wherein
the semiconductor substrate has a top portion and a bottom portion,
the top portion of the semiconductor substrate is electrically isolated from the bottom portion of the semiconductor substrate by the impurity layer,
the first plug is electrically connected to the top portion of the semiconductor substrate and is electrically insulated from the bottom portion of the semiconductor substrate, and
the first plug partially overlaps with the first conductor in plan view.

11. The semiconductor device according to claim 1, further comprising:
a dummy pattern formed below the first conductor, wherein
the dummy pattern partially overlaps with the first conductor, in plan view.

12. The semiconductor device according to claim 1, further comprising:
a chain resistor in which a plurality of wirings and a plurality of plugs are electrically connected, wherein
the chain resistor overlaps with the first conductor in plan view.

13. The semiconductor device according to claim 12, wherein
the chain resistor is formed along an entire circumference of the periphery of the semiconductor substrate.

14. The semiconductor device according to claim 1, further comprising:
a capacitor in which a third wiring and the first conductor are electrically connected, wherein
the third wiring overlaps with the first conductor, in plan view.

15. The semiconductor device according to claim 14, wherein
the capacitor is formed along an entire circumference of the periphery of the semiconductor substrate.
